(19) United States
(12) Patent Application Publication
(10) Pub. No.: US 2025/0044607 A1
(43) Pub. Date: Feb. 6, 2025

(54) DISPLAY DEVICE

(71) Applicant: SAMSUNG DISPLAY CO., LTD., Yongin-si (KR)

(72) Inventors: Beom Shik KIM, Yongin-si (KR); Eun Kyoung NAM, Yongin-si (KR); Jeong Woo PARK, Yongin-si (KR)

(21) Appl. No.: 18/658,105

(22) Filed: May 8, 2024

(30) Foreign Application Priority Data
Aug. 1, 2023 (KR) 10-2023-0100642

(51) Int. Cl. G02B 30/28; G02F 1/1333; G02F 1/1335; G02F 1/1343

(52) U.S. Cl. CPC G02B 30/28; G02F 1/133357; G02F 1/133528; G02F 1/134309; G02F 1/13439

(57) ABSTRACT

A display device includes a display layer generating light. The display layer includes a plurality of pixels. A polarizing layer polarizes the light generated by the display layer. A first optical layer is disposed on the polarizing layer. The first optical layer includes a first lens array and a first electrode on the first lens array. A liquid crystal layer is disposed on the first optical layer. The liquid crystal layer includes liquid crystal molecules. A second optical layer is disposed on the liquid crystal layer. The second optical layer includes a second lens array and a second electrode disposed on the second lens array. The first optical layer and the second optical layer are symmetrical to each other with respect to the liquid crystal layer.

### CROSS-REFERENCE TO RELATED APPLICATION

This application claims priority under 35 U.S.C. § 119 to Korean Patent Application No. 10-2023-0100642, filed on Aug. 1, 2023 in the Korean Intellectual Property Office, the disclosure of which is incorporated by reference in its entirety herein.

### 1. TECHNICAL FIELD

One or more embodiments of the present disclosure described herein relate to a display device.

### 2. DISCUSSION OF RELATED ART

Research has been actively conducted for developing display devices along with the rapid advancement of the information society. The development of a method or device for implementing a 3D display is currently researched and attempted in many different fields due to consumer demand for viewing 3D images.

A 2D/3D switchable display technology that enables a 2D image and a 3D image to be selectively implemented in a display device has been developed. A liquid crystal lens type in which an optical path difference is formed like a lens, using a liquid crystal layer, may be used in the 2D/3D switchable display technology.

An electric field distribution control method using characteristics of liquid crystals aligned according to an electric field is used as an example of the liquid crystal lens type. In the electric field distribution control method, the 3D performance may be deteriorated due to a low refractive index difference of a liquid crystal layer.

### SUMMARY

Embodiments of the present disclosure provide an increased 3D performance of a display device to which an electric field distribution control method is applied in a liquid crystal lens type.

According to an embodiment of the present disclosure, a display device includes a display layer generating light. The display layer includes a plurality of pixels. A polarizing layer polarizes the light generated by the display layer. A first optical layer is disposed on the polarizing layer. The first optical layer includes a first lens array and a first electrode on the first lens array. A liquid crystal layer is disposed on the first optical layer. The liquid crystal layer includes liquid crystal molecules. A second optical layer is disposed on the liquid crystal layer. The second optical layer includes a second lens array and a second electrode disposed on the second lens array. The first optical layer and the second optical layer are symmetrical to each other with respect to the liquid crystal layer.

In an embodiment, the first optical layer may further include a first substrate supporting the first lens array and a first planarization layer disposed over the first electrode. The first planarization layer planarizing a surface of the first optical layer.

In an embodiment, the second optical layer may further include a second substrate supporting the second lens array and a second planarization layer disposed over the second electrode. The second planarization layer planarizing a surface of the second optical layer.

In an embodiment, the first lens array may include at least one first lens. The at least one first lens includes a convex surface. The at least one first lens is arranged such that the convex surface thereof faces the liquid crystal layer.

In an embodiment, the second lens array may include at least one second lens. The at least one second lens includes a convex surface. The at least one second lens is disposed such that the convex surface thereof faces the convex surface of the at least one first lens.

In an embodiment, the first planarization layer and the second planarization layer may be adjacent to the liquid crystal layer.

In an embodiment, a distance between a center of the at least one first lens and a center of the at least one second lens may be the shortest distance as compared to distances between all other portions of the at least one first lens to the at least one second lens. A distance between an edge of the at least one first lens and an edge of the at least one second lens may be the longest distance as compared to the distances between all other portions of the at least one first lens to the at least one second lens.

In an embodiment, when a voltage is applied to the first electrode and the second electrode, the liquid crystal molecules overlapping with the center of the at least one first lens and the center of the at least one second lens may be aligned in a direction vertical to the liquid crystal layer. The liquid crystal molecules overlapping with the edge of the at least one first lens and the edge of the at least one second lens may be aligned in a direction horizontal to the liquid crystal layer.

In an embodiment, a smallest refractive index of the liquid crystal layer may be at a first portion where the center of the at least one first lens and the center of the at least one second lens overlap with each other. A largest refractive index of the liquid crystal layer is at a second portion where the edge of the at least one first lens and the edge of the at least one second lens overlap with each other.

In an embodiment, the first lens array may include at least one first lens. The at least one first lens includes a convex surface. The at least one first lens is arranged such that the convex surface thereof faces away from the liquid crystal layer.

In an embodiment, the second lens array may include at least one second lens. The at least one second lens includes a convex surface. The at least one second lens is arranged such that the convex surface thereof faces away from the convex surface of the at least one first lens.

In an embodiment, the first substrate and the second substrate may be adjacent to the liquid crystal layer.

In an embodiment, a distance between a center of the at least one first lens and a center of the at least one second lens may be the longest distance as compared to distances between all other portions of the at least one first lens to the at least one second lens. A distance between an edge of the at least one first lens and an edge of the at least one second lens may be the shortest distance as compared to the distances between all other portions of the at least one first lens to the at least one second lens.

In an embodiment, when a voltage is applied to the first electrode and the second electrode, the liquid crystal molecules overlapping with the center of the at least one first lens and the center of the at least one second lens may be aligned in a direction horizontal to the liquid crystal layer. The liquid crystal molecules overlapping with the edge of the at least one first lens and the edge of the at least one second lens may be aligned in a direction vertical to the liquid crystal layer.

In an embodiment, a largest refractive index of the liquid crystal layer may be at a first portion where the center of the at least one first lens and the center of the at least one second lens overlap with each other. The smallest refractive index of the liquid crystal layer is at a second portion where the edge of the at least one first lens and the edge of the at least one second lens overlap with each other.

In an embodiment, the first planarization layer may be composed of a same resin as the first lens array, and the second planarization layer may be composed of a same resin as the second lens array.

In an embodiment, each of the first substrate and the second substrate may be a transparent substrate.

In an embodiment, each of the first electrode and the second electrode may be a transparent electrode.

In an embodiment, when there is no voltage applied to the first electrode and the second electrode, the display device may operate in a 2D mode. A 2D image is displayed by the display device in the 2D mode.

In an embodiment, when a voltage is applied to the first electrode and the second electrode, the display device may operate in a 3D mode. A 3D image is displayed by the display device in the 3D mode.

### BRIEF DESCRIPTION OF THE DRAWINGS

The above and other features of embodiments of the present disclosure will become more apparent by describing in further detail non-limiting embodiments thereof with reference to the accompanying drawings, in which:

FIG. 1 is a view illustrating a schematic structure of a display device and a method of displaying a 2D image in accordance with an embodiment of the present disclosure.

FIG. 2 is a view illustrating the schematic structure of the display device and a method of displaying a 3D image in accordance with an embodiment of the present disclosure.

FIG. 3 is a schematic cross-sectional view illustrating a display device in the 2D mode in accordance with an embodiment of the present disclosure.

FIG. 4 is a graph illustrating a refractive index of a liquid crystal layer in the 2D mode according to FIG. 3 in accordance with an embodiment of the present disclosure.

FIG. 5 is a schematic cross-sectional view illustrating the display device in the 3D mode in accordance with an embodiment of the present disclosure.

FIG. 6 is a graph illustrating a refractive index of a liquid crystal layer in the 3D mode according to FIG. 5 in accordance with an embodiment of the present disclosure.

FIG. 7 is a schematic cross-sectional view illustrating a display device in the 2D mode in accordance with an embodiment of the present disclosure.

FIG. 8 is a schematic cross-sectional view illustrating the display device in the 3D mode in accordance with an embodiment of the present disclosure.

FIG. 9 is a graph illustrating a refractive index of a liquid crystal layer in the 3D mode according to FIG. 8.

### DETAILED DESCRIPTION OF EMBODIMENTS

The present disclosure now will be described more fully hereinafter with reference to the accompanying drawings, in which various non-limiting embodiments are shown. The present disclosure may, however, be embodied in many different forms, and should not be construed as limited to the described embodiments set forth herein.

In describing the drawings, like reference numerals have been used for like elements. In the accompanying drawings, the dimensions of the structures may be enlarged to clearly explain the present disclosure. It will be understood that, although the terms “first”, “second”, etc. may be used herein to describe various elements, these elements should not be limited by these terms. These terms are only used to distinguish one element from another element. For instance, a first element discussed below could be termed a second element without departing from the scope of embodiments of the present disclosure. Similarly, the second element could also be termed the first element.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

In the following description, when a first part is “connected” to a second part, this includes not only an embodiment in which the first part is directly connected to the second part, but also an embodiment in which a third part is interposed therebetween and they are connected to each other. However, when a first part is described as being “directly connected” to a second part, no elements may be interposed therebetween.

Furthermore, relative terms, such as “lower” or “bottom” and “upper” or “top,” may be used herein to describe the relationship of one element to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Hereinafter, embodiments of the present disclosure will be described in detail with reference to the accompanying drawings.

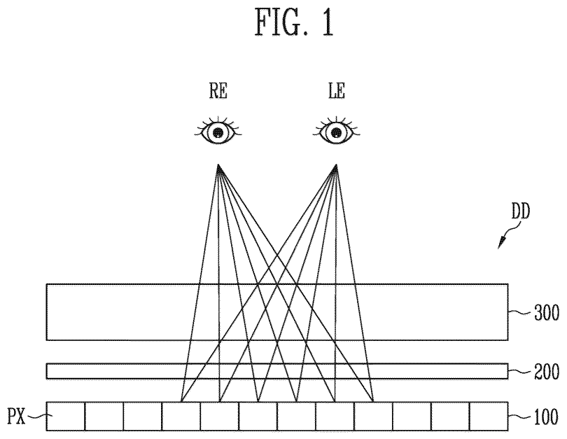

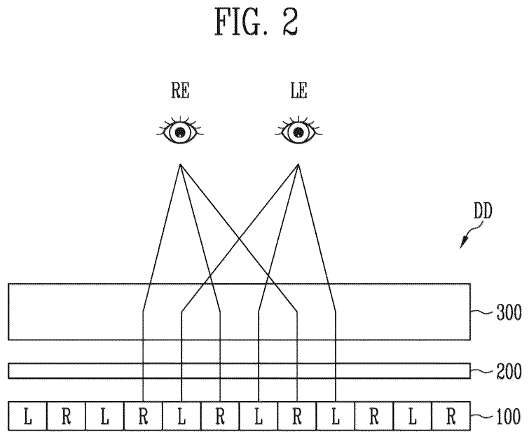

FIG. 1 is a view illustrating a schematic structure of a display device and a method of displaying a 2D image in accordance with an embodiment of the present disclosure. FIG. 2 is a view illustrating the schematic structure of the display device and a method of displaying a 3D image in accordance with an embodiment of the present disclosure.

Referring to FIGS. 1 and 2, a display device DD in accordance with an embodiment of the present disclosure may include a display layer 100, a polarizing layer 200, and a light modulation layer 300. The display device DD may operate in a 2D mode in which a 2D image is displayed or a 3D mode in which a 3D image is displayed.

The display layer 100 may be a component for displaying an image. For example, the display layer 100 may be a component for generating light. The display layer 100 may include a plurality of pixels PX for displaying an image. In an embodiment, the display layer 100 may be a light emitting display layer. For example, the display layer 100 may be an organic light emitting display layer, an inorganic light emitting display layer, an organic-inorganic light emitting display layer, a micro LED display layer, a nano LED display layer, or a quantum dot display layer. However, embodiments of the present disclosure are not necessarily limited thereto, and the display layer 100 may be implemented in various forms as long as the display layer 100 is a component for generating light according to an electrical signal.

Referring to FIG. 1, in an embodiment the display layer 100 may display one planar image in the 2D mode. Referring to FIG. 2, in an embodiment the display layer 100 may display an image corresponding to several viewing zones, using a space division method or a time division method, in the 3D mode. For example, the display layer 100 may alternately display a left eye image L and a right eye image R for every pixels PX (see FIG. 1) of one column in the 3D mode.

The polarizing layer 200 may be disposed on the display layer 100. In an embodiment, the polarizing layer 200 may be attached to the display layer 100 through an adhesive layer including an optically clear adhesive (OCA), a pressure sensitive adhesive (PSA), and the like. The polarizing layer 200 may polarize light generated in the display layer 100. In an embodiment, the polarizing layer 100 may linearly polarize light incident from the display layer 100. For example, light which is emitted from the display layer 100 and passes through the polarizing layer 200 may be horizontally polarized or vertically polarized. Hereinafter, for convenience of description, it is assumed that the polarizing layer 200 vertically polarizes light emitted from the display layer 100. However, embodiments of the present disclosure are not necessarily limited thereto, and a direction in which the light emitted from the display layer 100 is polarized may vary according to a kind of the polarizing layer 200.

The light modulation layer 300 may be disposed on the polarizing layer 200. In an embodiment, the light modulation layer 300 may be attached to the polarizing layer 200 through an adhesive layer including an optically clear adhesive (OCA), a pressure sensitive adhesive (PSA), and the like.

The light modulation layer 300 may convert a driving mode of the display device DD. For example, the light modulation layer 300 may convert the driving mode of the display device DD from the 3D mode to the 2D mode or from the 2D mode to 3D mode. Referring to FIG. 1, the light modulation layer 300 may operate such that a 2D image output from the display layer 100 is transmitted therethrough as it is when the display device DD is in the 2D mode. Accordingly, the same image reaches a left eye LE and a right eye RE, so that a user can perceive the image as a 2D image.

Referring to FIG. 2, the light modulation layer 300 may operate such that a 2D image output from the display layer 100 is converted into a 3D image when the display device DD is in the 3D mode. For example, the light modulation layer 300 may refract a left eye image L and a right eye image R, which are output from the display layer 100 in the 3D mode, thereby allowing an image to be formed in a viewing zone corresponding to each viewpoint image. Accordingly, the left eye image L and the right eye image R respectively reach the left eye LE and the right eye RE, so that the user can perceive a 3D image according to a binocular disparity.

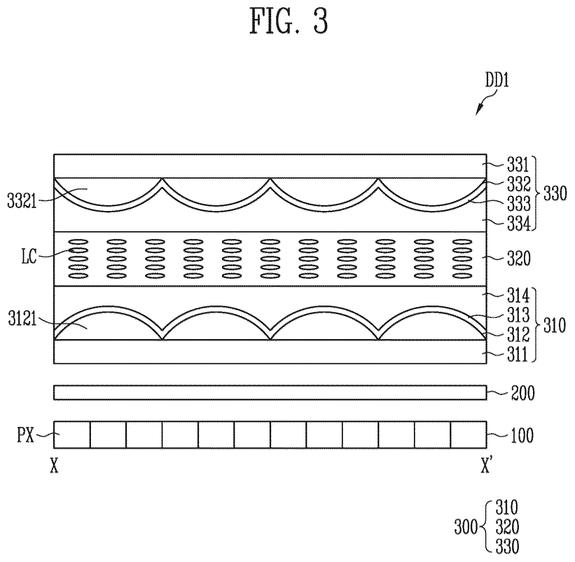

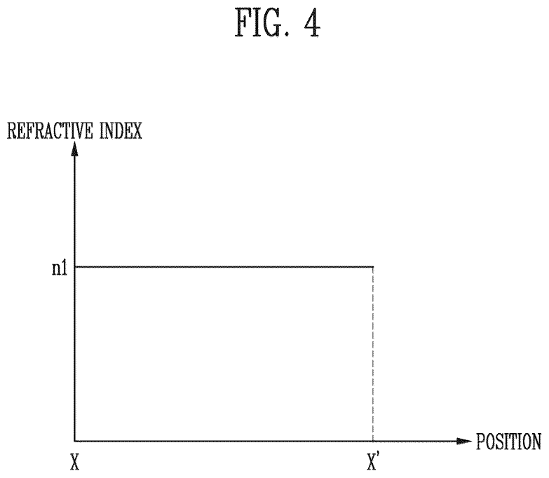

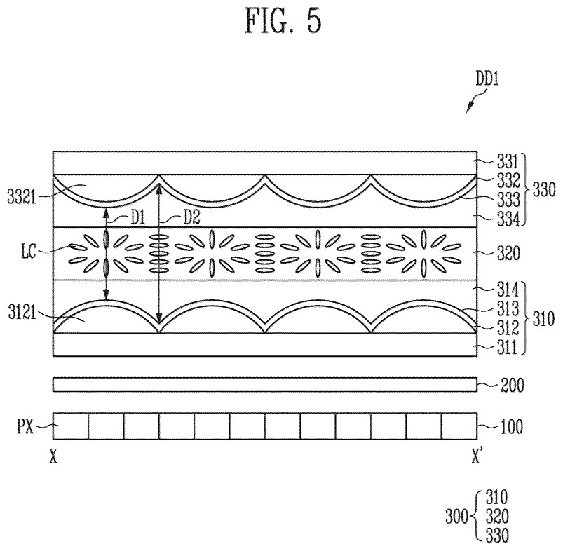

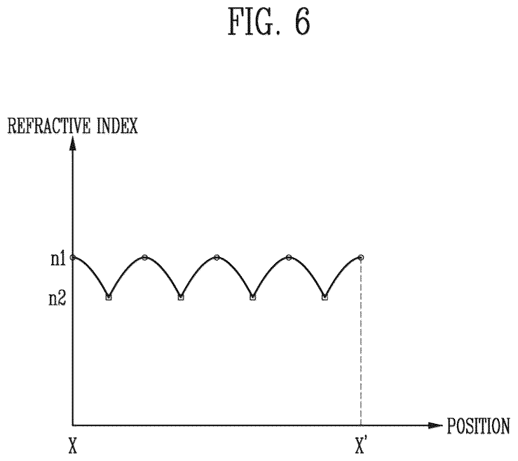

FIG. 3 is a schematic cross-sectional view illustrating a display device in the 2D mode in accordance with an embodiment of the present disclosure. FIG. 4 is a graph illustrating a refractive index of a liquid crystal layer in the 2D mode according to FIG. 3. FIG. 5 is a schematic cross-sectional view illustrating the display device in the 3D mode in accordance with an embodiment of the present disclosure. FIG. 6 is a graph illustrating a refractive index of a liquid crystal layer in the 3D mode according to FIG. 5.

For example, in FIGS. 3 and 5, a schematic cross-sectional view of a light modulation layer 300 in accordance with an embodiment of the present disclosure is illustrated, and descriptions of portions overlapping with those described above may be omitted or simplified for economy of description.

Referring to FIGS. 3 and 5, a display device DD1 in accordance with an embodiment of the present disclosure may include a display layer 100, a polarizing layer 200, and a light modulation layer 300. The display device DD1 in accordance with an embodiment of the present disclosure may selectively display a 2D image and a 3D image, using an electric field distribution control method.

In an embodiment, the light modulation layer 300 may include a first optical layer 310, a liquid crystal layer 320, and a second optical layer 330. In an embodiment, the first optical layer 310 and the second optical layer 330 may be symmetrical to each other with respect to the liquid crystal layer 320. In an embodiment in which the first optical layer 310 and the second optical layer 330 have a symmetrical structure, a change in an electric field generated by the first optical layer 310 and the second optical layer 330 increases, and hence the alignment distribution (e.g., differences in alignment) of liquid crystal molecules LC of the liquid crystal layer 320 may increase. Thus, a refractive index difference according to a position of the liquid crystal layer 320 increases, so that the 3D performance of the display device DD1 can be increased. This will be described in detail later.

The first optical layer 310 may be disposed on the polarizing layer 200. In an embodiment, the first optical layer 310 may be attached to the polarizing layer 200 through an adhesive layer, such as an optically clear adhesive (OCA), a pressure sensitive adhesive (PSA), and the like.

In an embodiment, the first optical layer 310 may include a first substrate 311, a first lens array 312, a first electrode 313, and a first planarization layer 314.

The first substrate 311 may be a component for supporting the first lens array 312. In an embodiment, the first substrate 311 may be a transparent substrate. For example, in an embodiment the first substrate 311 may be made of a transparent film such as polyimide (PI), polyamide (PA), or polyethylene terephthalate (PET). However, embodiments of the present disclosure are not necessarily limited thereto. For example, in some embodiments the first substrate 311 may be a translucent substrate or an opaque substrate.

The first lens array 312 may be disposed on the first substrate 311. The first lens array 312 may include at least one first lens 3121 which refracts light incident from a plurality of pixels PX. For example, in an embodiment the first lens array 312 may be implemented as a lenticular lens array, a micro lens array, or the like. In an embodiment, a pitch (e.g., a horizontal width) of the at least one first lens 3121 may correspond to three pixels PX. However, embodiments of the present disclosure are not necessarily limited thereto, and the number of pixels PX corresponding to the pitch of the at least one first lens 3121 may vary.

In an embodiment, the at least one first lens 3121 may be disposed such that a convex surface thereof faces the liquid crystal layer 320. For example, the at least one first lens 3121 may be disposed such that the convex surface faces upwards.

The first electrode 313 may be disposed on (e.g., disposed directly thereon) the first lens array 312. For example, in an embodiment the first electrode 313 may be disposed to cover the entire surface of the first lens array 312. However, embodiments of the present disclosure are not necessarily limited thereto, and the first electrode 313 may be patterned to respectively correspond to the at least one first lens 3121. In an embodiment, the first electrode 313 may be a transparent electrode. For example, the first electrode 313 may be made of a transparent conductive material such as indium tin oxide (ITO) or indium zinc oxide (IZO). However, embodiments of the present disclosure are not necessarily limited thereto.

The first planarization layer 314 may be disposed over (e.g., directly above) the first electrode 313. The first planarization layer 314 may planarize an upper surface of the first optical layer 310. In an embodiment, the first planarization layer 314 may be disposed adjacent to (e.g., directly adjacent thereto) the liquid crystal layer 320 (e.g., in the vertical direction). In an embodiment, the first planarization layer 314 may be made of (e.g., composed of) the same resin as the first lens array 312. For example, in an embodiment the first planarization layer 314 and the first lens array 312 may be made of photocurable resin such as acrylate resin. However, embodiments of the present disclosure are not necessarily limited thereto.

As such, the first optical layer 310 in accordance with an embodiment of the present disclosure may have a structure in which the first substrate 311, the first lens array 312, the first electrode 313, and the first planarization layer 314 are sequentially stacked (e.g., in the vertical direction) when viewed on a plane.

The second optical layer 330 may be disposed on the liquid crystal layer 320. In an embodiment, the second optical layer 330 may include a second substrate 331, a second lens array 332, a second electrode 333, and a second planarization layer 334.

The second substrate 331 may be a component for supporting the second lens array 332. In an embodiment, the second substrate 331 may be a transparent substrate. For example, in an embodiment the second substrate 331 may be made of a transparent film such as polyimide (PI), polyamide (PA), or polyethylene terephthalate (PET). However, embodiments of the present disclosure are not necessarily limited thereto. For example, in an embodiment the second substrate 331 may be a translucent substrate or an opaque substrate.

The second lens array 332 may be disposed on the second substrate 331. The second lens array 332 may include at least one second lens 3321 which refracts light passing through the liquid crystal layer 320. For example, in an embodiment the second lens array 332 may be implemented as a lenticular lens array, a micro lens array, or the like.

In an embodiment, the at least one second lens 3321 may be disposed such that a convex surface thereof faces the liquid crystal layer 320. For example, the at least one second lens 3321 may be disposed such that the convex surface faces downwards. Accordingly, the convex surface of the at least one second lens 3321 may face the convex surface of the at least one first lens 3121. In an embodiment the at least one second lens 3321 may be disposed to be symmetrical to the at least one first lens 3121 with respect to the liquid crystal layer 320.

In an embodiment, a distance (e.g., in the vertical direction) between a center of the at least one first lens 3121 and a center of the at least one second lens 3321 may be the shortest. The centers of the at least one first lens 3121 and the at least one second lens 3321 may be defined in a direction that is horizontal to the liquid crystal layer 320 (e.g., an upper surface of the liquid crystal layer 320). For example, when the convex surface of the at least one first lens 3121 and the convex surface of the at least one second lens 3321 face each other, the distance between the center of the at least one first lens 3121 and the center of the at least one second lens 3321 may be the shortest (e.g., in the vertical direction) as compared to the distances between the other portions of the at least one first lens 3121 with respect to the at least one second lens 3321.

In an embodiment, a distance between an edge (e.g., a lateral edge) of the at least one first lens 3121 and an edge (e.g., a lateral edge) of the at least one second lens 3321 may be the longest (e.g., in the vertical direction). For example, when the convex surface of the at least one first lens 3121 and the convex surface of the at least one second lens 3321 face each other, the distance between the edge of the at least one first lens 3121 and the edge of the at least one second lens 3321 may be the longest as compared to the distances between the other portions of the at least one first lens 3121 with respect to the at least one second lens 3321.

The second electrode 333 may be disposed on (e.g., disposed directly thereon) the second lens array 332. For example, in an embodiment the second electrode 333 may be disposed to cover the entire surface of the second lens array 332. However, embodiments of the present disclosure are not necessarily limited thereto, and the second electrode 333 may be patterned to respectively correspond to the at least one second lens 3321. In an embodiment, the second electrode 333 may be a transparent electrode. For example, in an embodiment the second electrode 333 may be made of a transparent conductive material such as indium tin oxide (ITO) or indium zinc oxide (IZO). However, embodiments of the present disclosure are not necessarily limited thereto.

In an embodiment, a distance (e.g., in the vertical direction) between the first electrode 313 and the second electrode 333 may be the shortest at a position at which the center of the first lens 3121 and the center of the second lens 3321 overlap with each other. For example, referring to FIG. 5, when the convex surface of the at least one first lens 3121 and the convex surface of the at least one second lens 3321 face each other, a distance D1 between the first electrode 313 disposed at the center of the at least one first lens 3121 and the second electrode 333 disposed at the center of the at least one second lens 3321 may be the shortest distance as compared to the distances between the other portions of the first electrode 313 and the second electrode 333.

In an embodiment, the distance between the first electrode 313 and the second electrode 333 may be the longest (e.g., in a vertical direction) at a position at which the edge of the first lens 3121 and the edge of the second lens 3321 overlap with each other. For example, referring to FIG. 5, when the convex surface of the at least one first lens 3121 and the convex surface of the at least one second lens 3321 face each other, a distance D2 between the first electrode 313 disposed at the edge of the at least one first lens 3121 and the second electrode 333 disposed at the edge of the at least one second lens 3321 may be the longest distance as compared to the distances between the other portions of the first electrode 313 and the second electrode 333.

The second planarization layer 334 may be disposed over (e.g., directly below) the second electrode 333. The second planarization layer 334 may planarize a lower surface of the second optical layer 330. In an embodiment, the second planarization layer 334 may be disposed adjacent (e.g., directly adjacent thereto) to the liquid crystal layer 320 (e.g., in the vertical direction). In an embodiment, the second planarization layer 334 may be made of the same resin as the second lens array 332. For example, the second planarization layer 334 and the second lens array 332 may be made of photocurable resin such as acrylate resin. However, embodiments of the present disclosure are not necessarily limited thereto.

As such, the second optical layer 310 in accordance with an embodiment of the present disclosure may have a structure in which the second planarization layer 334, the second electrode 333, the second lens array 332, and the second substrate 331 are sequentially stacked (e.g., in the vertical direction) when viewed on a plane.

The liquid crystal layer 320 may be disposed on the first optical layer 310. Also, the liquid crystal layer 320 may be disposed between the first optical layer 310 and the second optical layer 330 (e.g., in the vertical direction). The liquid crystal layer 320 may include liquid crystal molecules LC having a thin and long structure. The liquid crystal molecules LC have a polarization property that an arrangement direction thereof is changed according to an electric field. For example, the arrangement direction of the liquid crystal molecules LC may be changed by an electric field formed by a voltage applied to the first electrode 313 and the second electrode 333. Hereinafter, for convenience of description, it is assumed that the arrangement direction of the liquid crystal molecules LD is determined based on an arrangement direction of long portions of the liquid crystal molecules LC. However, embodiments of the present disclosure are not necessarily limited thereto, and the arrangement direction of the liquid crystal molecules LC may be determined based on an arrangement direction of short portions of the liquid crystal molecules LC.

In an embodiment, a phase change of light incident onto the liquid crystal layer 320 may vary according to the arrangement direction of the liquid crystal molecules. For example, when the arrangement direction of the liquid crystal molecules LC and a polarization direction of light correspond with each other, the phase change of light may be relatively large. On the other hand, when the arrangement direction of the liquid crystal molecules LC and the polarization direction of light do not correspond with each other, the phase change of light may be relatively small. As such, a difference in refractive index (e.g., a difference in transmittance) of the liquid crystal layer 320 occurs according to the arrangement direction of the liquid crystal molecules LC, and therefore, light incident onto the liquid crystal layer 320 may exhibit different phase changes with respect to positions thereof. For example, as the difference in refractive index of the liquid crystal layer 320 becomes larger, the distribution of the phase change of light becomes more diverse and wider, so that the 3D performance of the display device DD1 can be increased.

Referring to FIG. 3, in an embodiment a voltage may not be applied to the first electrode 313 and the second electrode 333 in the 2D mode of the display device DD1. For example, an electrical field may not be formed between the first electrode 313 and the second electrode 333 in the 2D mode of the display device DD1. Therefore, the arrangement direction of the liquid crystal molecules LC of the liquid crystal layer 320 may not be changed. Accordingly, as shown in FIG. 3, in an embodiment the arrangement direction of the liquid crystal molecules LC of the liquid crystal layer 320 may be maintained in a direction horizontal to the liquid crystal layer 320 in the 2D mode of the display device DD1. For example, the alignment distribution of liquid crystal molecules LC of the liquid crystal layer 320 may be small in the 2D mode of the display device DD1.

Referring to FIG. 4, there may be no difference in refractive index according to a position of the liquid crystal layer 320 in the 2D mode of the display device DD1. For example, the refractive index according to the position of the liquid crystal layer 320 may be constant as n1 in the 2D mode of the display device DD1 between points X and X′ of the display device DD1 shown in FIG. 3. For example, since the arrangement direction of the liquid crystal molecules LC is constant in the direction horizontal to the liquid crystal layer 320 in the 2D mode of the display device DD1, there may be no difference in refractive index of the liquid crystal layer 320 between points X and X′. Therefore, the liquid crystal layer 320 may act as a transmission layer, thereby allowing light emitted from the display layer 100 to be transmitted therethrough as it is in the 2D mode of the display device DD1.

Referring to FIG. 5, a voltage may be applied to the first electrode 313 and the second electrode 333 in the 3D mode of the display device DD1. Thus, an electric field may be formed between the first electrode 313 and the second electrode 333 in the 3D mode of the display device DD1. Therefore, the arrangement direction of the liquid crystal molecules LC of the liquid crystal layer 320 may be changed according to the electric field. For example, the alignment distribution (e.g., differences in alignment) of the liquid crystal molecules LC of the liquid crystal layer 320 may be large in the 3D mode of the display device DD1.

In an embodiment, liquid crystal molecules LC located at a position at which the center of the at least one first lens 3121 and the center of the at least one second lens 3321 overlap with each other may be aligned in a direction vertical to the liquid crystal layer 320 (e.g., aligned in the vertical direction). The greatest intensity of the electric field acting on the liquid crystal layer 320 may be at a position at which the distance between the first electrode 313 and the second electrode 333 is the shortest. Therefore, an alignment change of the liquid crystal molecules LC located at the position at which the center of the at least one first lens 3121 and the center of the at least one second lens 3321 overlap with each other may be the largest. For example, the alignment of liquid crystal molecules LC located at a position at which the center of the at least one first lens 3121 and the center of the at least one second lens 3321 overlap with each other may be changed from the direction horizontal to the liquid crystal layer 320 to the direction vertical to the liquid crystal layer 320 based on the voltage applied to the first electrode 313 and the second electrode 333.

In an embodiment, liquid crystal molecules LC located at a position at which the edge of the at least one first lens 3121 and the edge of the at least one second lens 3321 overlap with each other may be aligned in the direction horizontal to the liquid crystal layer 320. The intensity of the electric field acting on the liquid crystal layer 320 may be smallest at a position at which the distance between the first electrode 313 and the second electrode 333 is the longest. Therefore, an alignment change of the liquid crystal molecules LC located at the position at which the edge of the at least one first lens 3121 and the edge of the at least one second lens 3321 overlap with each other may be the smallest. For example, in an embodiment as the alignment of the liquid crystal molecules LC located at the position at which the edge of the at least one first lens 3121 and the edge of the at least one second lens 3321 overlap with each other maintains the direction horizontal to the liquid crystal layer 320, the alignment of the liquid crystal molecules LC may not be changed from when the display device DD1 is in the 2D mode.

In FIG. 6, points indicated by a circle represent positions at which the refractive index is n1, and points indicated by a quadrangle represent positions at which the refractive index is n2. Referring to FIG. 6, a difference in refractive index according to a position of the liquid crystal layer 320 may occur in the 3D mode of the display device DD1. For example, in the 3D mode of the display device DD1, the refractive index of the liquid crystal layer 320 may be the largest as n1 at the position at which the edge of the at least one first lens 3121 and the edge of the at least one second lens 3321 overlap with each other. This is because the polarization direction of light and the arrangement direction of the liquid crystal molecules LC correspond with each other as the horizontal direction. Also, in the 3D mode of the display device DD1, the refractive index of the liquid crystal layer 320 may be the smallest as n2 at the position at which the center of the at least one first lens 3121 and the center of the at least one second lens 3321 overlap with each other. This is because the polarization direction of light is the horizontal direction, but the arrangement direction of the liquid crystal molecules LC is the vertical direction instead of the horizontal direction.

As such, a distance change between the first electrode 313 and the second electrode 333 may increase in a structure in which the convex surface of the at least one first lens 3121 and the convex surface of the at least one second lens 3321 face each other (e.g., in the vertical direction). As a result, the difference in refractive index according to the position of the liquid crystal layer 320 increases, so that the 3D performance of the display device DD1 can be increased.

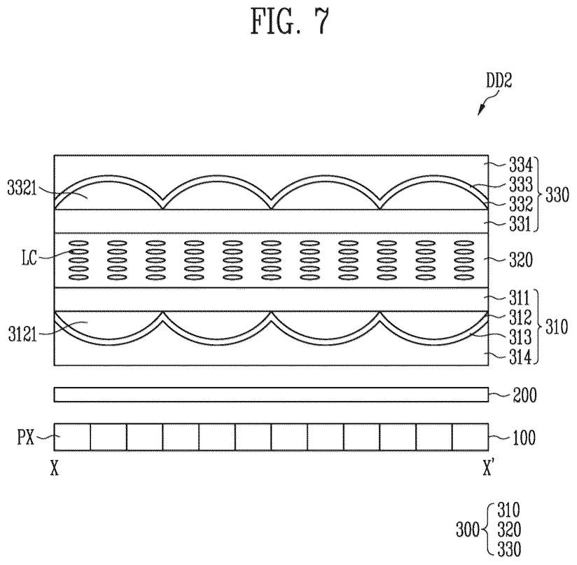

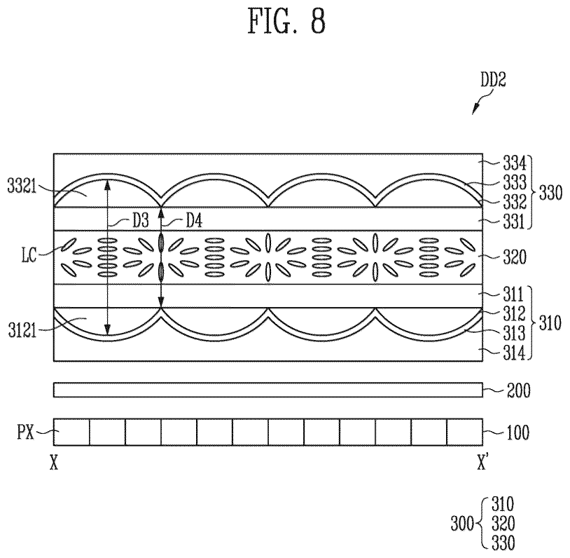

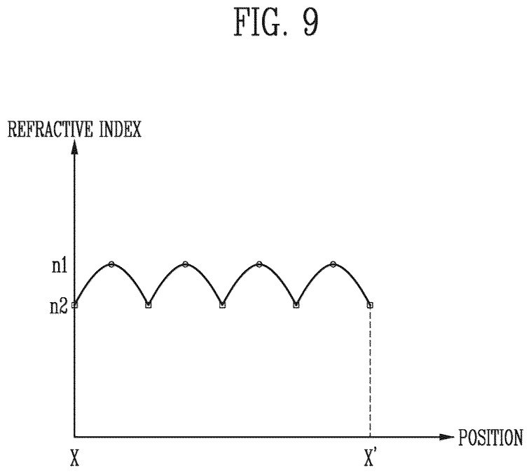

FIG. 7 is a schematic cross-sectional view illustrating a display device in the 2D mode in accordance with an embodiment of the present disclosure. FIG. 8 is a schematic cross-sectional view illustrating the display device in the 3D mode in accordance with an embodiment of the present disclosure. FIG. 9 is a graph illustrating a refractive index of a liquid crystal layer in the 3D mode according to FIG. 8.

Particularly, in FIGS. 7 and 8, a schematic cross-sectional view of a light modulation layer 300 in accordance with an embodiment of the present disclosure is illustrated, and descriptions of portions overlapping with those described above will be omitted or simplified.

Referring to FIGS. 7 and 8, a display device DD2 in accordance with an embodiment of the present disclosure may include a display layer 100, a polarizing layer 200, and a light modulation layer 300. The display device DD2 in accordance with the embodiment of the present disclosure may selectively display a 2D image and a 3D image, using an electric field distribution control method.

In the display device DD2 in accordance with an embodiment of the present disclosure, a first optical layer 310 and a second optical layer 330 may be symmetrical to each other with respect to a liquid crystal layer 320. An effect provided when the first optical layer 310 and the second optical layer 330 have a symmetrical structure may be the same as described above.

In an embodiment, the at least one first lens 3121 may be disposed such that a convex surface thereof does not face the liquid crystal layer 320. For example, the at least one first lens 3121 may be disposed such that the convex surface thereof face downwards and away from the liquid crystal layer 320.

In an embodiment, at least one second lens 3321 may be disposed such that a convex surface thereof does not face the liquid crystal layer 320. For example, the at least one second lens 3321 may be disposed such that the convex surface thereof faces upwards and away from the liquid crystal layer 320. Accordingly, the convex surface of the at least one second lens 3321 may not face the convex surface of the at least one first lens 3121 and may face away from the convex surface of the at least one first lens. As such, the at least one second lens 3321 may be disposed to be symmetrical to the at least one first lens 3121 with respect to the liquid crystal layer 320.

In an embodiment, a distance between a center of the at least one first lens 3121 and a center of the at least second lens 3321 may be the longest as compared to the distances between the other portions of the at least one first lens 3121 with respect to the at least one second lens 3321. For example, in an embodiment in which the convex surface of the at least one first lens 3121 and the convex surface of the at least one second lens 3321 do not face each other and are symmetrical to each other, the distance between the center of the at least one first lens 3121 and the center of the at least second lens 3321 may be the longest.

In an embodiment, a distance between an edge of the at least one first lens 3121 and an edge of the at least second lens 3321 may be the shortest as compared to the distances between the other portions of the at least one first lens 3121 with respect to the at least one second lens 3321. For example, in an embodiment in which the convex surface of the at least one first lens 3121 and the convex surface of the at least one second lens 3321 do not face each other and are symmetrical to each other, the distance between the edge of the at least one first lens 3121 and the edge of the at least second lens 3321 may be the shortest.

In an embodiment, a distance between a first electrode 313 and a second electrode 333 may be the longest at a position at which the center of the first lens 3121 and the center of the second lens 3321 overlap with each other. For example, referring to FIG. 8, in an embodiment in which the convex surface of the at least one first lens 3121 and the convex surface of the at least one second lens 3321 do not face each other and are symmetrical to each other, a distance D3 between the first electrode 313 disposed at the center of the at least one first lens 3121 and the second electrode 333 disposed at the center of the at least one second lens 3321 may be the longest as compared to the distances between the other portions of the first electrode 313 and the second electrode 333.

In an embodiment, the distance between the first electrode 313 and the second electrode 333 may be the shortest at a position at which the edge of the first lens 3121 and the edge of the second lens 3321 overlap with each other. For example, referring to FIG. 8, in an embodiment in which the convex surface of the at least one first lens 3121 and the convex surface of the at least one second lens 3321 do not face each other, a distance D4 between the first electrode 313 disposed at the edge of the at least one first lens 3121 and the second electrode 333 disposed at the edge of the at least one second lens 3321 may be the shortest as compared to the distances between the other portions of the first electrode 313 and the second electrode 333.

In an embodiment, a first planarization layer 314 may planarize a lower surface of the first optical layer 310. In an embodiment, a first substrate 311 may be disposed adjacent to the liquid crystal layer 320 (e.g., in the vertical direction).

In an embodiment, a second planarization layer 334 may planarize an upper surface of the second optical layer 330. In an embodiment, the second substrate 331 may be disposed adjacent to the liquid crystal layer 320 (e.g., in the vertical direction).

As such, the first optical layer 310 in accordance with an embodiment of the present disclosure may have a structure in which the first planarization layer 314, the first electrode 313, a first lens array 312, and the substrate 311 are sequentially stacked (e.g., in the vertical direction) when viewed on a plane. In addition, the second optical layer 330 in accordance with an embodiment of the present disclosure may have a structure in which the second substrate 331, a second lens array 332, the second electrode 333, and the second planarization layer 334 are sequentially stacked (e.g., in the vertical direction) when viewed on a plane.

Referring to FIG. 7, in the 2D mode of the display device DD2, there is no voltage applied to the first electrode 313 and the second electrode 333, and hence an electric field may not be formed between the first electrode 313 and the second electrode 333. Therefore, an arrangement direction of liquid crystal molecules LC of the liquid crystal layer 320 may not be changed. For example, in an embodiment, in the 2D mode of the display device DD2, the arrangement direction of the liquid crystal molecules LC of the liquid crystal layer 320 is maintained in a direction horizontal to the liquid crystal layer 320, and therefore, the alignment distribution (e.g., differences in the alignment) of the liquid crystal molecules LC of the liquid crystal layer 320 may be small. Like FIG. 4, there may be no difference in refractive index according to a position of the liquid crystal layer 320 in the 2D mode of the display device DD2.

Referring to FIG. 8, in the 3D mode of the display device DD2, a voltage is applied to the first electrode 313 and the second electrode 333, and hence an electric field may be formed between the first electrode 313 and the second electrode 333. Therefore, the arrangement direction of the liquid crystal molecules LC of the liquid crystal layer 320 may be changed according to the electric field. For example, the alignment distribution (e.g., differences in alignment) of the liquid crystal molecules LC of the liquid crystal layer 320 may be large in the 3D mode of the display device DD2.

In an embodiment, liquid crystal molecules LC located at a position at which the center of the at least one first lens 3121 and the center of the at least one second lens 3321 overlap with each other may be aligned in a direction horizontal to the liquid crystal layer 320. The intensity of the electric field acting on the liquid crystal layer 320 may be the smallest at a position at which the distance between the first electrode 313 and the second electrode 333 is the longest. Therefore, an alignment change of the liquid crystal molecules LC located at the position at which the center of the at least one first lens 3121 and the center of the at least one second lens 3321 overlap with each other may be the smallest. For example, in an embodiment, as the alignment of the liquid crystal molecules LC located at the position at which the center of the first lens 3121 and the center of the second lens 3321 overlap with each other maintains the direction horizontal to the liquid crystal layer 320, the alignment of the liquid crystal molecules LC may not be changed.

In an embodiment, liquid crystal molecules LC located at a position at which the edge of the at least one first lens 3121 and the edge of the at least one second lens 3321 overlap with each other may be aligned in a direction vertical to the liquid crystal layer 320. The intensity of the electric field acting on the liquid crystal layer 320 may be largest at a position at which the distance between the first electrode 313 and the second electrode 333 is the shortest. Therefore, an alignment change of the liquid crystal molecules LC located at the position at which the edge of the at least one first lens 3121 and the edge of the at least one second lens 3321 overlap with each other may be the largest. For example, the alignment of liquid crystal molecules LC located at a position at which the edge of the first lens 3121 and the edge of the second lens 3321 overlap with each other may be changed from the direction horizontal to the liquid crystal layer 320 to the direction vertical to the liquid crystal layer 320 (e.g., the vertical direction).

In FIG. 9, points indicated by a circle represent positions at which the refractive index is n1, and points indicated by a quadrangle represent positions at which the refractive index is n2. Referring to FIG. 9, a difference in refractive index according to a position of the liquid crystal layer 320 may occur in the 3D mode of the display device DD2. For example, in the 3D mode of the display device DD2, the refractive index of the liquid crystal layer 320 may be the largest as n1 at the position at which the center of the at least one first lens 3121 and the center of the at least one second lens 3321 overlap with each other. This is because the polarization direction of light and the arrangement direction of the liquid crystal molecules LC correspond with each other as the horizontal direction. Also, in the 3D mode of the display device DD2, the refractive index of the liquid crystal layer 320 may be the smallest as n2 at the position at which the edge of the at least one first lens 3121 and the edge of the at least one second lens 3321 overlap with each other. This is because the polarization direction of light is the horizontal direction, but the arrangement direction of the liquid crystal molecules LC is the vertical direction instead of the horizontal direction.

As such, a distance change between the first electrode 313 and the second electrode 333 may increase in a structure in which the convex surface of the at least one first lens 3121 and the convex surface of the at least one second lens 3321 do not face each other. As a result, the difference in refractive index according to the position of the liquid crystal layer 320 increases, so that the 3D performance of the display device DD1 can be increased.

In accordance with embodiments of the present disclosure, 3D performance of a display device to which an electric field distribution control method is applied in a liquid crystal lens type can be increased.

Although the present disclosure has been specifically described according to the above-described embodiments, it should be noted that the above-described embodiments are intended to illustrate the present disclosure and not to limit the scope of embodiments of the present disclosure. Those of ordinary skill in the art to which the present disclosure pertains will understand that various modifications are possible within the scope of the technical spirit of the present disclosure.

Therefore, the technical protection scope of the present disclosure is not limited to the described embodiments. In addition, all changes or modifications derived from the meaning and scope of the claims and their equivalents should be construed as being included in the scope of the present disclosure. The described embodiments may be combined to form additional embodiments.

What is claimed is:

1. A display device comprising:
a display layer generating light, the display layer including a plurality of pixels;
a polarizing layer polarizing the light generated by the display layer;
a first optical layer disposed on the polarizing layer, the first optical layer including a first lens array and a first electrode on the first lens array;
a liquid crystal layer disposed on the first optical layer, the liquid crystal layer including liquid crystal molecules; and
a second optical layer disposed on the liquid crystal layer, the second optical layer including a second lens array and a second electrode disposed on the second lens array,
wherein the first optical layer and the second optical layer are symmetrical to each other with respect to the liquid crystal layer.

2. The display device of claim 1, wherein the first optical layer further includes:
a first substrate supporting the first lens array; and
a first planarization layer disposed over the first electrode, the first planarization layer planarizing a surface of the first optical layer.

3. The display device of claim 2, wherein the second optical layer further includes:
a second substrate supporting the second lens array; and
a second planarization layer disposed over the second electrode, the second planarization layer planarizing a surface of the second optical layer.

4. The display device of claim 3, wherein:
the first lens array includes at least one first lens, the at least one first lens includes a convex surface, wherein the at least one first lens is arranged such that the convex surface thereof faces the liquid crystal layer.

5. The display device of claim 4, wherein:
the second lens array includes at least one second lens, the at least one second lens includes a convex surface, wherein the at least one second lens is disposed such that the convex surface thereof faces the convex surface of the at least one first lens.

6. The display device of claim 4, wherein the first planarization layer and the second planarization layer are adjacent to the liquid crystal layer.

7. The display device of claim 5, wherein:
a distance between a center of the at least one first lens and a center of the at least one second lens is a shortest distance as compared to distances between all other portions of the at least one first lens to the at least one second lens; and
a distance between an edge of the at least one first lens and an edge of the at least one second lens is a longest distance as compared to the distances between all other portions of the at least one first lens to the at least one second lens.

8. The display device of claim 7, wherein, when a voltage is applied to the first electrode and the second electrode,
the liquid crystal molecules overlapping with the center of the at least one first lens and the center of the at least one second lens are aligned in a direction vertical to the liquid crystal layer, and
the liquid crystal molecules overlapping with the edge of the at least one first lens and the edge of the at least one second lens are aligned in a direction horizontal to the liquid crystal layer.

9. The display device of claim 8, wherein:
a smallest refractive index of the liquid crystal layer is at a first portion where the center of the at least one first lens and the center of the at least one second lens overlap with each other; and
a largest refractive index of the liquid crystal layer is at a second portion where the edge of the at least one first lens and the edge of the at least one second lens overlap with each other.

10. The display device of claim 3, wherein the first lens array includes at least one first lens, the at least one first lens includes a convex surface, wherein the at least one first lens is arranged such that the convex surface thereof faces away from the liquid crystal layer.

11. The display device of claim 10, wherein the second lens array includes at least one second lens, the at least one second lens includes a convex surface, wherein the at least one second lens is arranged such that the convex surface thereof faces away from the convex surface of the at least one first lens.

12. The display device of claim 10, wherein the first substrate and the second substrate are adjacent to the liquid crystal layer.

13. The display device of claim 11, wherein:
a distance between a center of the at least one first lens and a center of the at least one second lens is a longest distance as compared to distances between all other portions of the at least one first lens to the at least one second lens; and
a distance between an edge of the at least one first lens and an edge of the at least one second lens is a shortest distance as compared to the distances between all other portions of the at least one first lens to the at least one second lens.

14. The display device of claim 13, wherein, when a voltage is applied to the first electrode and the second electrode,
the liquid crystal molecules overlapping with the center of the at least one first lens and the center of the at least one second lens are aligned in a direction horizontal to the liquid crystal layer, and
the liquid crystal molecules overlapping with the edge of the at least one first lens and the edge of the at least one second lens are aligned in a direction vertical to the liquid crystal layer.

15. The display device of claim 14, wherein:
a largest refractive index of the liquid crystal layer is at a first portion where the center of the at least one first lens and the center of the at least one second lens overlap with each other; and
a smallest refractive index of the liquid crystal layer is at a second portion where the edge of the at least one first lens and the edge of the at least one second lens overlap with each other.

16. The display device of claim 3, wherein:
the first planarization layer is composed of a same resin as the first lens array; and
the second planarization layer is composed of a same resin as the second lens array.

17. The display device of claim 3, wherein each of the first substrate and the second substrate is a transparent substrate.

18. The display device of claim 1, wherein each of the first electrode and the second electrode is a transparent electrode.

19. The display device of claim 1, wherein, when there is no voltage applied to the first electrode and the second electrode, the display device operates in a 2D mode, wherein a 2D image is displayed by the display device in the 2D mode.

20. The display device of claim 1, wherein, when a voltage is applied to the first electrode and the second electrode, the display device operates in a 3D mode, wherein a 3D image is displayed by the display device in the 3D mode.
